(19) United States
(12) Patent Application Publication
(10) Pub. No.: US 2025/0380436 A1
(43) Pub. Date: Dec. 11, 2025

(54) METHODS OF MANUFACTURING BIPOLAR JUNCTION DEVICES

(71) Applicant: IDEAL POWER INC., Austin, TX (US)

(72) Inventors: Jiankang BU, Austin, TX (US); Mudit KHANNA, Austin, TX (US); R. Daniel BRDAR, Driftwood, TX (US)

(73) Assignee: IDEAL POWER INC., Austin, TX (US)

(21) Appl. No.: 19/199,481

(22) Filed: May 6, 2025

Related U.S. Application Data
(60) Provisional application No. 63/658,508, filed on Jun. 11, 2024.

(51) Int. Cl. H10D 10/01; H10D 10/60

(52) U.S. Cl. CPC H10D 10/061; H10D 10/60

(57) ABSTRACT

Bipolar junction devices, and methods for manufacturing the same. At least one example of making a bipolar junction device includes doping an upper side of a substrate with an upper P-type region and an upper N-type region, thermally diffusing the upper P-type region and the upper N-type region, the substrate having a thickness of greater than 150 microns during the thermally diffusing, reducing the thickness of the substrate to between and including 40 and 150 microns, doping a lower side of the substrate with a lower P-type region and a lower N-type region, and then localized-heat annealing the lower P-type region and the lower N-type region.

### CROSS-REFERENCE TO RELATED APPLICATIONS

This application claims the benefit of U.S. Provisional Application No. 63/658,508, filed on Jun. 11, 2024. The entire disclosure of the application referenced above is incorporated herein by reference.

### FIELD

The present disclosure relates to bipolar junction devices, and more particularly to methods of making bipolar junction devices.

### BACKGROUND

For double-sided bipolar junction devices, such as B-TRAN™ brand devices manufactured by Ideal Power Inc. of Austin, Texas, the on-state voltage drop or conduction loss is related to the thickness of the device-thicker devices have greater on-state conduction loss. However, the thickness of the device also controls the voltage blocking capability or voltage rating. For example, bipolar junction devices rated for 1200V service may have a thickness of between 240 and 280 microns. That is, while thinner devices may have lower conduction loss, thinner devices also have a lower voltage rating.

It follows, when manufacturing double-sided bipolar junction devices with lower voltage ratings (e.g., 400V or 600V), less device thickness may be needed for voltage blocking; however, it may be difficult to manufacture the device because a thinner wafer is subject to cracking during thermal processes, such as the thermal annealing to activate or diffuse doping regions.

### SUMMARY

A method of making a bipolar junction device includes doping an upper side of a substrate with an upper P-type region and an upper N-type region, thermally diffusing the upper P-type region and the upper N-type region, the substrate having a thickness of greater than 150 microns during the thermally diffusing, reducing the thickness of the substrate to between and including 40 and 150 microns, doping a lower side of the substrate with a lower P-type region and a lower N-type region, and localized-heat annealing the lower P-type region and the lower N-type region.

In other features, the method further includes, prior to reducing the thickness of the substrate, placing a metal layer on the upper side that directly electrically couples the upper P-type region to the upper N-type region. The upper P-type region is displaced from the upper N-type region. The method further includes, after localized-heat annealing the lower P-type region and the lower N-type region, placing a metal layer on the lower side that directly electrically couples the lower P-type region to the lower N-type region. The lower P-type region is displaced from the lower N-type region.

In other features, the substrate is a least one selected from a group comprising: N-type; and P-type. The method further includes creating lattice imperfections in the substrate. Creating the lattice imperfections comprises at least one selected from a group comprising: ion implantation; ion implantation of He+; and exposure of the substrate to radiation by electrons. Creating the lattice imperfections comprises ion implantation of about 4-5 mega-electron Volt (MeV) He+ helium atoms. Creating the lattice imperfections comprises exposing the substrate to radiation by electrons at between and including 120 kilogray (kGy) and 250 kGy.

In other features, the method further includes creating upper lattice imperfections by ion implantation incident initially upon the upper side and creating lower lattice imperfections by ion implantation incident initially upon the lower side. The upper P-type region has a depth about 10 microns, and the lower P-type region has a depth of about 5 microns. Prior to reducing the thickness, the substrate has a thickness of between and including 200 and 800 microns. Reducing the thickness comprises reducing the thickness to between and comprising 45 to 120 microns. Reducing the thickness comprises reducing the thickness to about 45 microns for the bipolar junction device rated for 400V service. Reducing the thickness comprises reducing the thickness to about 70 microns for the bipolar junction device rated for 600V service.

In other features, localized-heat annealing further includes laser annealing. Localized-heat annealing further comprises plasma annealing. Localized-heat annealing further comprises annealing by way of an infrared lamp.

In other features, a bipolar junction device is made using various methods described herein.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

For a detailed description of example embodiments, reference will now be made to the accompanying drawings in which:

FIG. 1 shows an overhead view of a bipolar junction device at an intermediate stage of construction of the device, and in accordance with at least some embodiments;

FIG. 2 shows a cross-sectional view of the bipolar junction device, taken substantially along line 2-2 of FIG. 1, and in accordance with at least some embodiments;

FIG. 3 shows a cross-sectional view of the bipolar junction device with upper metallization that electrically shorts the upper P-type region to the upper N-type region, in accordance with at least some embodiments;

FIG. 4 shows a cross-sectional view of the bipolar junction device with lower metallization that electrically shorts the lower P-type region to the lower N-type region, in accordance with at least some embodiments;

FIG. 5 shows a cross-sectional view of the bipolar junction device in accordance with at least some embodiments;

FIG. 6 shows a cross-sectional view of the bipolar junction device at an intermediate stage of the construction, in accordance with at least some embodiments;

FIG. 7 shows a cross-sectional view of the bipolar junction device at an intermediate stage of the construction, in accordance with at least some embodiments;

FIG. 8 shows a cross-sectional view of the bipolar junction device at an intermediate stage of the construction, in accordance with at least some embodiments;

FIG. 9 shows a cross-sectional view of the bipolar junction device at an intermediate stage of the construction, in accordance with at least some embodiments;

FIG. 10 shows a cross-sectional view of the bipolar junction device at an intermediate stage of the construction, in accordance with at least some embodiments;

FIG. 11 shows a cross-sectional view of the bipolar junction device after creation of the lattice imperfections, and in accordance with at least some embodiments; and

FIG. 12 shows a method in accordance with at least some embodiments.

### DEFINITIONS

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or a direct connection. Thus, if a first device couples to a second device, that connection may be through a direct connection or through an indirect connection via other devices and connections.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions. To be clear, an initial reference to “a [referent]”, and then a later reference for antecedent basis purposes to “the [referent]”, shall not obviate that the recited referent may be plural.

“About” in reference to a recited parameter shall mean the recited parameter plus or minus ten percent (+/−10%) of the recited parameter.

“Thermally diffusing” or “thermal diffusion” shall mean a diffusion or activation step that takes place in a heated chamber (e.g., at 800° C. to 1150° C.). Thus, during thermal diffusion the entire wafer may be brought to the annealing temperature.

“Localized-heat annealing” or “localized-heat anneal” shall mean a diffusion or activation step in which the surface temperature of the wafer may reach to between and including 800° C. to 1100° C., but the depth penetration of the heat is less than thermal diffusion. Localized-heat annealing includes, singly or in combination: laser annealing (sometimes called “rapid thermal annealing” (RTA)) in which the heat for diffusion or activation is provided by a laser incident upon the surface of the substrate; argon or other plasma annealing in which the heat for diffusion or activation is provided by way of the plasma; and infrared lamp heating in which the heat for diffusion or activation is provided by exposure to infrared photons.

“Upper” in reference to component (e.g., upper collector-emitter) shall not be read to imply a location of the recited component with respect to gravity. Upper may be derived from location of the device in an example drawing.

“Lower” in reference to a component (e.g., lower collector-emitter, lower base) shall not be read to imply a location of the recited component with respect to gravity. Lower may be derived from location of the device in an example drawing.

“Ohmic contact” shall mean a non-rectifying electrical junction between two materials (e.g., a metal and a semiconductor).

“Controller” shall mean, alone or in combination, individual circuit components, an application specific integrated circuit (ASIC), a microcontroller with controlling software, a reduced-instruction-set computing (RISC) with controlling software, a digital signal processor (DSP), a processor with controlling software, a programmable logic device (PLD), a field programmable gate array (FPGA), or a programmable system-on-a-chip (PSOC), configured to read inputs and drive outputs responsive to the inputs.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Various examples are directed to methods of manufacturing double-sided bipolar junction devices. More particularly, various examples are directed to manufacturing unidirectional and bidirectional double-sided bipolar junction devices. More particularly still, various examples are directed to manufacturing techniques in which an upper side of the double-sided bipolar junction device is created using one or more high temperature thermal processes (e.g., thermal annealing, thermal activation, or thermal diffusion), and a lower side of the double-sided bipolar junction device is created using one more low temperature thermal processes or localized-heat annealing (e.g., laser annealing, plasma annealing, infrared lamp annealing), such that the thickness of the device during processing of the lower side may be between and including 40 and 150 microns. The specification now turns to an example bipolar junction device.

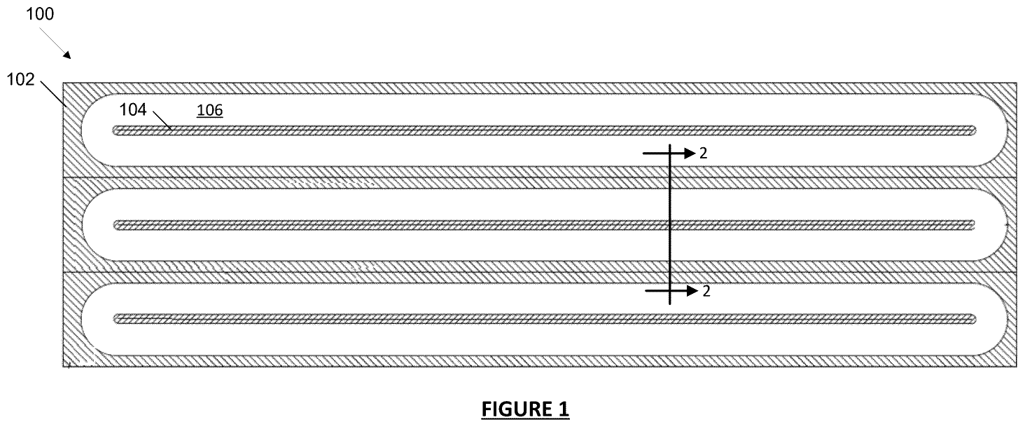

FIG. 1 shows an overhead view of a bipolar junction device 100 at an intermediate stage of construction of the device. In particular, the example bipolar junction device 100 includes P-type regions (e.g., P+) surrounding and separated from N-type regions (e.g., N+). For example, an upper P-type region 102 encompasses or surrounds an upper N-type region 104. While three N-type regions are shown surrounded by the P-type region, any number of such arrangements may be included depending upon the current carrying capability of the bipolar junction device 100. Exposed between the upper P-type region 102 and the upper N-type region 104 is the silicon substrate 106, with the substrate 106 being N-type in this example.

The example bipolar junction device 100 is a double-sided device. Thus, while FIG. 1 shows an overhead view at an intermediate stage of the construction of the upper side of the device, FIG. 1 may also be said to show a lower side view at an intermediate stage of construction of the lower side of the device. As the example bipolar junction device 100 is created on a single substrate, the intermediate stages exist at different times in the construction, as will be discussed in greater detail below.

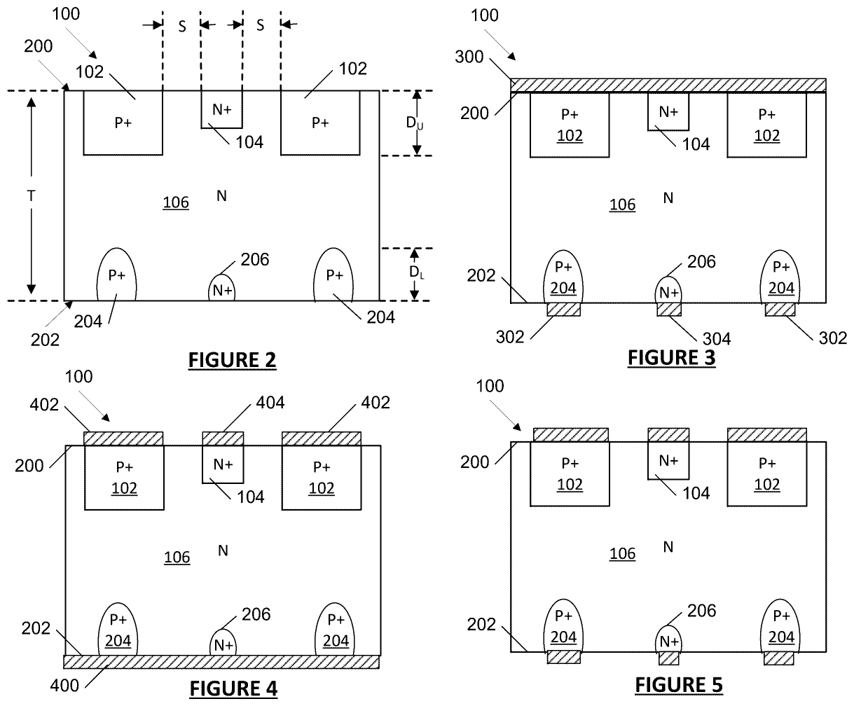

FIG. 2 shows a cross-sectional view of the example bipolar junction device 100, taken substantially along line 2-2 of FIG. 1. In particular, FIG. 2 shows the example bipolar junction device 100 defines a top or upper side 200 and a bottom or lower side 202. The terms “upper” and “lower” shall not be read to imply a location of the recited component with respect to gravity; rather, and as here, upper and lower may be derived from a location within the example figure.

Visible in FIG. 2, in association with the upper side 200, are both sides of the upper P-type region 102, along with the upper N-type region 104. FIG. 2 shows that the upper N-type region 104 is spaced apart or displaced from the surrounding upper P-type region 104. In some examples, the upper N-type region 104 is centered within the obround shape defined by an inside surface of the upper P-type region 102, and thus the displacement or spacing S between the upper N-type region 104 and the upper P-type region 102 may be about the same on each side of the upper N-type region 104.

FIG. 2 further shows a lower P-type region and lower N-type region. In particular, visible in the cross-sectional view are both sides of a lower P-type region 204, along with a lower N-type region 206. As with the upper regions, the lower N-type region 206 may be centered within an obround shape defined by an inside surface of the lower P-type region 204, and thus the displacement or spacing between the lower N-type region 206 and the lower P-type region 204 may be about the same on each side of the lower N-type region 206.

Each portion of the upper P-type region is illustratively shown to have a rectangular cross-section, and the upper N-type region 104 is likewise shown to have a rectangular cross-section. Each portion of the lower P-type region 204 is illustratively shown to have a semi-circular cross-section, and the lower N-type region 206 is likewise shown to have a semi-circular cross-section. These illustrative cross-sectional shapes are shown different not to imply actual cross-sectional shapes; rather, the differences are shown to highlight that the diffusion depth and shape, as between the various regions of the upper side 200 and the various regions of the lower side 202, may be different. In practice, the diffusion depth Du of the upper P-type region 102 may be about 10 microns, and the upper N-type region 104 may have a non-zero diffusion depth less than Du. The diffusion depth DL of the lower P-type region 204 may be about 5 microns, and the lower N-type region 206 having a non-zero diffusion depth less than DL.

As discussed in greater detail below, the differences in diffusion depth may be attributable to the difference in semiconductor processing steps used for creating the structures on the upper side 200 versus the lower the side 202. In particular, the structures associated with the upper side 200 may be created when the substrate 106 has a thickness T of greater than 150 microns (e.g., between and including 200 and 800 microns), while the structures associated with the lower side 202 may be created when the substrate 106 has a thickness T of between and including 40 and 150 microns.

Before discussing in detail the semiconductor processing steps, and in particular the differences in processing as between the upper side 200 and the lower side 202, the application turns to examples devices at or near completion of the semiconductor process.

FIG. 3 shows a cross-sectional view of the example bipolar junction device 100 with upper metallization that electrically shorts the upper P-type region 102 to the upper N-type region 104. In particular, FIG. 3 shows the bipolar junction device 100 having the upper P-type region 102, the upper N-type region 104, the lower P-type region 204, and the lower N-type region 206. The upper side 200 in this example includes an upper metal 300 layer that directly electrically couples the upper P-type region 102 and the upper N-type region 104. In various examples, the electrical connection of the upper metal 300 to the upper N-type region 104 is an ohmic connection (e.g., non-rectifying), and thus the additional metal layers may be present (e.g., titanium) to create the ohmic connection. Similarly, the electrical connection of the upper metal 300 to the upper P-type region 102 may be an ohmic connection. In one example, the electrical connection of the upper metal 300 to the substrate 106, between the regions 102 and 104, may be a rectifying connection (e.g., Schottky), and in other cases an insulation (e.g., oxide) may electrically isolate the upper metal 300 from the substrate 106 exposed between the upper P-type region 102 and the upper N-type region 104.

At different times in the construction of the device, the lower side 202 may likewise have metal deposited thereon; however, in the example of FIG. 3 the metal may be etched to electrically isolate the metal associated with the lower P-type region 204 and the lower N-type region 206. Thus, the lower side 202 is associated with metal contact 302 associated with lower P-type region 204, and metal contact 304 associated with lower N-type region 206. Operation of the example device of FIG. 3 may be as discussed in co-pending and commonly assigned U.S. Application No. 63/650,652 filed 22 May 2024 titled “Bipolar Junction Devices, and Methods and Switches Using Same.”

FIG. 4 shows a cross-sectional view of the example bipolar junction device 100 with lower metallization that electrically shorts the lower P-type region 204 to the lower N-type region 206. In particular, FIG. 4 shows the bipolar junction device 100 having the upper P-type region 102, the upper N-type region 104, the lower P-type region 204, and the lower N-type region 206. The lower side 202 in this example includes a lower metal 400 layer that directly electrically couples the lower P-type region 204 and the lower N-type region 206. In various examples, the electrical connection of the lower metal 400 to the lower N-type region 206 is an ohmic connection (e.g., non-rectifying), and thus additional metal layers may be present (e.g., titanium) to create the ohmic connection. Similarly, the electrical connection of the lower metal 400 to the lower P-type region 204 may be an ohmic connection. In one example, the electrical connection of the lower metal 400 to the substrate 106, between the regions 102 and 104, may be a rectifying connection (e.g., Schottky), and in other cases an insulation (e.g., oxide) may electrically isolate the lower metal 400 from the substrate 106 exposed between the lower P-type region 204 and the lower N-type region 206.

At different times in the construction of the device, the upper side 200 may likewise have metal deposited thereon; however, in the example of FIG. 4 the metal may be etched to electrically isolate the metal associated with the upper P-type region 102 and the upper N-type region 104. Thus, the upper side 200 is associated with metal contact 402 that is associated with upper P-type region 102, and metal contact 404 that is associated with upper N-type region 104. Operation of the example device of FIG. 4 may likewise be as discussed in co-pending and commonly assigned U.S. Application No. 63/650,652 noted above.

Referring simultaneously to FIGS. 3 and 4, the device of FIG. 3 likely has better minority carrier injection by way of the upper P-type region 102 when electrical current is flowing from the upper N-type region 104 to the lower N-type region 206, wherein to maintain charge neutrality in drift region 106, minority carrier injection from the P-type region 102 (e.g., holes) attracts same amount of electrons, several orders of magnitude higher than wafer doping (e.g. 1E16/cm3 during injection versus 1e13/cm3 wafer doping), and thus significantly lowers forward voltage drop between the upper N-type region 104 and to the lower N-type region 206. By contrast, the device of FIG. 4 likely has better current pinch-off when interrupting current flow from the lower N-type region 206 to the upper N-type region 104. Thus, each arrangement may find advantages in particular situations. FIG. 3 and FIG. 4 can also be operated in a way “dual side injection”, particularly applicable to an alternating current (AC) signal, as described in co-owned and commonly assigned U.S. application Ser. No. 18/422,469 filed 25 Jan. 2024 titled “Methods and Systems of Operating a Double-Sided Double-Base Bipolar Junction Transistor.”

FIG. 5 shows a cross-sectional view of the example bipolar junction device 100. In particular, FIG. 5 shows the bipolar junction device 100 with metal deposited on both the upper side 200 and the lower side 202; however, in the example of FIG. 5 neither the upper regions nor the lower regions are shorted in the final product. Operation of the device of FIG. 5 is as described in a plethora of applications directed to the B-TRAN™ brand double-sided bipolar junction device rated for 1200V service. The device of FIG. 5 varies from related-art devices in that the thickness is selected for lower voltage service, such as 400V or 600V, and the processing techniques used to create the device vary from related-art processing, as discussed immediately below.

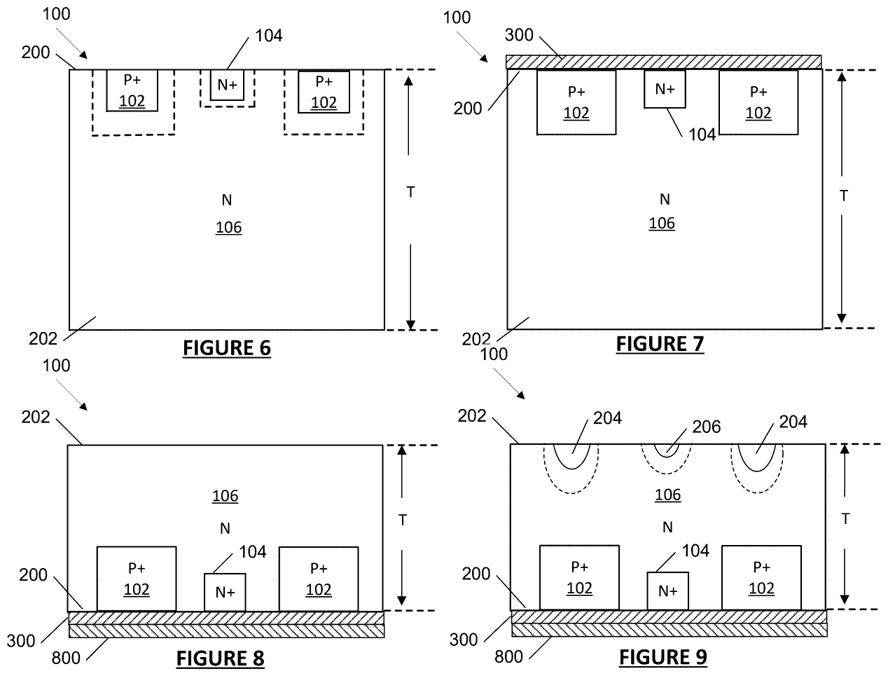

FIG. 6 shows a cross-sectional view of the example bipolar junction device 100 at an intermediate stage of the construction of the device. In particular, in the view of FIG. 6, the substrate 106 has a thickness T of greater than 150 microns, and in some cases between and including 200 and 800 microns. The upper P-type region 102 may be initially created using any suitable masking techniques (e.g., photoresist and photolithography) followed by a doping technique (e.g., boron implant). Similarly, the upper N-type region 104 may be initially created using any suitable masking techniques and doping technique (e.g., arsenic or phosphorus implant), though not necessarily at the same time or using the same techniques as the upper P-type region 102. However, after doping, the upper P-type region 102 and the upper N-type region 104 are activated by a diffusion step, and the diffusion step also results in physical expansion of the regions as the dopants migrate within the substrate 106.

At the stage of the construction represented by FIG. 6, the activation or diffusion may be carried out by way of a wafer-level thermal process. That is, because of the thickness T of the substrate, the overall wafer is not subject to cracking during high temperature thermal processes. Thus, in example cases, the upper P-type region 102 and the upper N-type region 104 are thermally diffused and/or activated, such as by the substrate 106 being placed within a heated chamber and raised to a temperature of between and including 800° C. to 1150° C. for an extended period of time (e.g., 12 to 24 hours). FIG. 6 illustratively shows the upper P-type region 102 and the upper N-type region 104 after diffusion by way of dashed lines.

Before proceeding, note that in the intermediate stage of construction illustrated by FIG. 6, there are no structures on the lower side 202. Moreover, the example doping and thermal diffusion to create the upper P-type region 102 and the upper N-type region 104 may be performed regardless of the desired end product, such as any of the devices of FIG. 3-5.

FIG. 7 shows a cross-sectional view of the example bipolar junction device 100 at an intermediate stage of the construction of the device. In particular, FIG. 7 shows the example bipolar junction device 100 after application of the upper metal 300 layer. FIG. 7 may thus represent an intermediate stage in creating of any of the devices of FIG. 3-5. Because of the thickness T at example stage of construction of between and including 200 and 800 microns, the example upper metal 300 may be created or deposited in any suitable form, such as through sputter or chemical vapor deposition (CVD). The electrical connection of the upper metal 300 to the upper N-type region 104 is an ohmic connection, and thus additional layers (e.g., titanium), and steps to create those layers, may be present but are not included so as not to unduly complicate the figure.

If the end layout of the bipolar junction device 100 is the arrangement of FIG. 3, then no further metal etch steps may be needed regarding the upper side 200. However, if the end layout of the bipolar junction device 100 is FIG. 4 or FIG. 5, then the example method may proceed to masking and etching the upper metal layer 300 to arrive at the desired layout for the upper side 200. For example, if FIG. 4 or 5 are the desired end layout, then additional photoresist masking and etching (e.g., plasma etch, wet etch) may be performed to remove the unwanted metal from the upper metal 300, such as removing metal that directly contacts the substrate 106.

The description that follows assumes that the desired end layout is that of FIG. 3. It will be understood, however, that the assumption is not a limitation on the scope of claims below; but rather; an expedient to aid in organizing and understanding the various embodiments.

In accordance with various examples, and after the creation of the structures on the upper side 200, the wafer is flipped and processing continues with respect to the lower side 202. In order to protect the previously created structures, the upper side 200 may be covered in some form, and thus protected. For example, the upper side 200 may be covered with a protective layer, such as photoresist or nitride. In other cases, the upper side 200 may be covered with a polymeric material held in place with an adhesive, such as “UV film” used in the semiconductor processing industry.

FIG. 8 shows a cross-sectional view of the bipolar junction device at an intermediate stage of the construction. In particular, FIG. 8 shows the example bipolar junction device 100 flipped (see the orientation of sides 200 and 202 as shown in the figure), and with a protective layer 800 covering the previously created structures, here the metal 300 layer. In spite of the bipolar junction device 100 being flipped, the original “upper side” will still be referred to as upper side 200, and the original “lower side” will still be referred to as lower side 202.

In various examples, after the protective layer 800 is applied, the substrate 106 is thinned to between and including 40 and 150 microns, depending upon the designed voltage rating for the finished bipolar junction device 100. For example, if the designed voltage rating is 400V, the substrate 106 may be thinned to about 45 microns or thicker. As another example, if the designed voltage rating is 600V, the substrate 106 may be thinned to about 70 microns or thicker.

Thinning of the substrate may take any suitable form. In one example, the substrate 106 thinned by grinding, sometimes referred to as “backside grind.” In other cases, the thinning may be by an etch process, such as a plasma etch or a wet etch. Regardless of the method used to perform the thinning, the resultant is that the thickness T is reduced to between and including 40 and 150 microns. The thinned wafer affects the ability to use some heat intensive semiconductor processing steps. For example, a thinned wafer may crack under the high temperature thermal processes, such as thermal diffusion. As another example, some metal deposition techniques may no longer be viable because of the temperature concerns. Stated otherwise, for the thinned wafer, the thermal budget for many traditional semiconductor processing steps may be too high. Moreover, thinned wafers may no longer be suitable for certain physical processes. For example, photolithography “stepper” machines used to selectively expose photoresist to light and/or photons may be too physically jarring, again subjecting the thinned wafer to cracking and/or breakage. For these reasons, and in accordance with various examples, the structures associated with the lower side 202 are created with lower thermal budget techniques, and techniques that avoid physically jarring the wafer.

FIG. 9 shows a cross-sectional view of the example bipolar junction device 100 at an intermediate stage of the construction. In particular, in the view of FIG. 9, the substrate 106 has a thickness of between and including 40 and 150 microns. The lower P-type region 204 may be initially created using a masking technique that results in reduced physical stress on the substrate 106, such as using a shadow mask. In particular, the shadow mask may define an internal surface that is a mirror image of the shape of the wafer, including structure(s) to mate with the primary or secondary flat of the wafer. The shadow mask may be made using any suitable material, such as a metallic material. The shadow mask may thus be placed over the wafer, and the dopants implanted through apertures in the shadow mask, in which the apertures define or outline regions that will become the lower P-type regions. Once the shadow mask is in place, the doping may take place using any suitable method.

Similarly, the lower N-type region 206 may be initially created using a shadow mask, separate and distinct from the shadow mask used in creating the lower P-type regions. In particular, the shadow mask for the lower N-type regions may likewise define an internal surface that is a mirror image of the wafer, and may be made any suitable material, such as a metallic material. The shadow mask for the lower N-type regions may thus be placed over the wafer, and the dopants implanted through apertures in the shadow mask.

After doping, the lower P-type region 204 and the lower N-type region 206 are activated by a diffusion step, and the diffusion step also results in physical expansion of the regions as the dopants migrate within the substrate 106. At the stage of the construction represented by FIG. 9, the activation or diffusion may be carried out using localized heating, such as localized-heat annealing as defined above. That is, because of the thickness T of the substrate of between and including 40 and 150 microns, wafer-level thermal processes, such as thermal diffusion, may cause cracking. Thus, in example cases, the lower P-type region 204 and the lower N-type region 206 are localized-heat annealed. In one example, the localized-heat annealing may result in internal wafer temperatures of less than 650° C., which may give less than 100% activation of the dopants as function of temperature and time (e.g., 50% or less, in some cases 30% or less, and in one case about 30%). FIG. 9 illustratively shows the lower P-type region 204 and the lower N-type region 206 after localized-heat annealing by way of dashed lines.

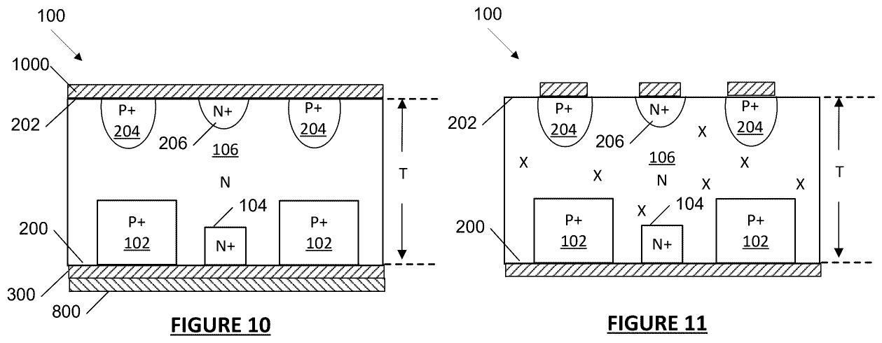

FIG. 10 shows a cross-sectional view of the example bipolar junction device 100 at an intermediate stage of the construction of the device. In particular, FIG. 10 shows the example bipolar junction device 100 after application of lower metal 1000 layer. Because of the thickness T at example stage of construction of between and including 40 and 150 microns, the example lower metal 1000 may be created or deposited in any suitable low temperature processes, such as OERLIKON® brand metal deposition processes available from OC Oerlikon of Switzerland. The OERLIKON® brand metal deposition processes have low thermal budgets, and thus the substrate 106 is not as susceptible to cracking caused by thermal expansion during the deposition process. The electrical connections of the lower metal 1000 to the lower P-type region 204 and the lower N-type region 206 may be ohmic connections, and thus additional layers (e.g., titanium), and steps to create those layers, may be present but are not included so as not to unduly complicate the figure and discussion.

The assumptions of the description at this point are that the end layout is the arrangement of FIG. 3. Thus, the example method may proceed to masking and etching the lower metal layer 1000 to arrive at the desired layout for the lower side 202. Moreover, the protective layer 800 may thereafter be removed, with the end result being the arrangement of FIG. 3.

One of ordinary skill in the art, with the benefit of this disclosure, could now modify the example methods to create any of the end layouts of FIGS. 3-5, using “thick wafer” processes when the substrate is thick, and using “thin wafer” processes when the substrate is thin.

In some examples, the next step in the method is creating lattice imperfections in the substrate. In particular, lattice imperfections within the substrate become recombination centers, facilitating the recombination of electron and holes. The number and location of lattice imperfections are related to the switching speed of the bipolar junction device 100. Creation of the lattice imperfections may take any suitable form. For example, the lattice imperfections may be created by exposing the substrate to high-energy ions, such as helium atoms (e.g., He+), protons, or nitrogen. In one particular example, the substrate 106 may be subject to ion implantation of about 4-5 Mega-electron Volt (MeV) He+ helium atoms. The lattice imperfections created by ion implantation may have limited depth with the substrate, such as 10-15 microns beneath the surface upon which the ions are incident. Thus, in some cases creating the lattice imperfections may involve creating upper lattice imperfections by ion implantation incident upon the upper side 200; and separately creating lower lattice imperfections by ion implantation incident upon the lower side 202.

In yet still other cases, the lattice imperfections may be created by radiation damage within the substrate 106. In particular, exposure of the substrate to high-energy radiation, such as X-rays, gamma rays, and neutron irradiation, causes lattice imperfections. Lattice imperfections created by high-energy radiation exposure are less limited in depth than ion implantation methods. In fact, for substrate 106 thickness T of between and including 40 and 150 microns, the lattice imperfections may be randomly spaced throughout the substrate, with the density of such lattice imperfections controlled by the radiation dose. In one example, the lattice imperfections may be created by exposing the substrate to electron radiation at between and including 120 kilogray (kGy) and 250 (kGy).

FIG. 11 shows a cross-sectional view of the bipolar junction device 100 after creation of the lattice imperfections. In particular, the example lattice imperfections, the locations shown with X's, are scattered throughout the substrate. Thus, FIG. 11 may represent creation of lattice imperfections by way of the electron radiation. However, regardless of the technique used, the end result is the bipolar junction device 100 comprising the lattice imperfections.

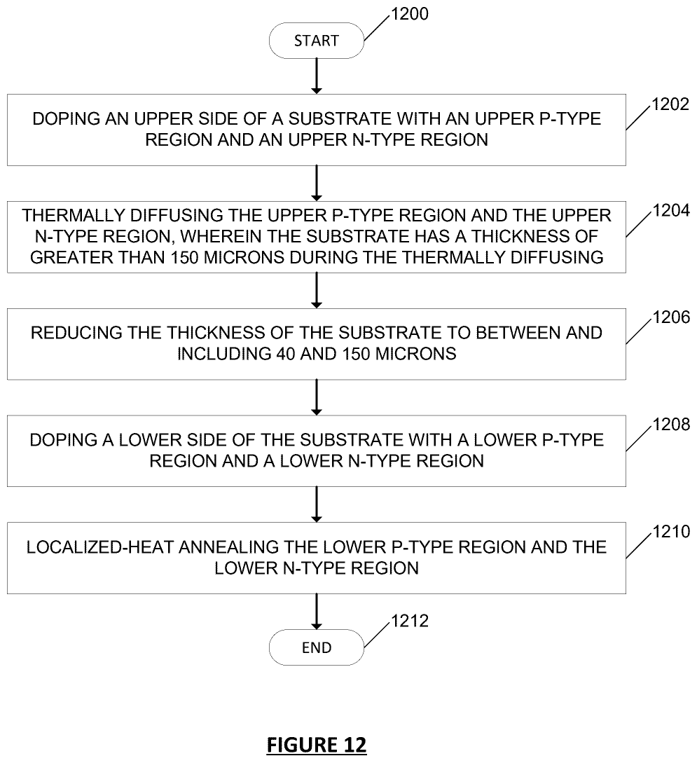

FIG. 12 shows a method of making a bipolar junction device. In particular, the method starts (block 1200) and comprises: doping an upper side of a substrate with an upper P-type region and an upper N-type region (block 1202); thermally diffusing the upper P-type region and the upper N-type region, wherein the substrate has a thickness of greater than 150 microns during the thermally diffusing (block 1204); reducing the thickness of the substrate to between and including 40 and 150 microns (block 1206); doping a lower side of the substrate with a lower P-type region and a lower N-type region (block 1208); and localized-heat annealing the lower P-type region and the lower N-type region (block 1210). Thereafter, the method ends (block 1212).

The above discussion is meant to be illustrative of the principles and various embodiments of the present invention. Numerous variations and modifications will become apparent to those skilled in the art once the above disclosure is fully appreciated. For example, while the various structures of FIGS. 2-11 are shown as PNP structures, the various techniques are equally applicable to the NPN structures. It is intended that the following claims be interpreted to embrace all such variations and modifications.

What is claimed is:

1. A method of making a bipolar junction device, the method comprising:
doping an upper side of a substrate with an upper P-type region and an upper N-type region; and then
thermally diffusing the upper P-type region and the upper N-type region, wherein the substrate has a thickness of greater than 150 microns during the thermally diffusing; and then
reducing the thickness of the substrate to between and including 40 and 150 microns; and then
doping a lower side of the substrate with a lower P-type region and a lower N-type region; and then
localized-heat annealing the lower P-type region and the lower N-type region.

2. The method of claim 1 further comprising, prior to reducing the thickness of the substrate, placing a metal layer on the upper side that directly electrically couples the upper P-type region to the upper N-type region.

3. The method of claim 2 wherein the upper P-type region is displaced from the upper N-type region.

4. The method of claim 1 further comprising, after localized-heat annealing the lower P-type region and the lower N-type region, placing a metal layer on the lower side that directly electrically couples the lower P-type region to the lower N-type region.

5. The method of claim 4 wherein the lower P-type region is displaced from the lower N-type region.

6. The method of claim 1 wherein the substrate is a least one selected from a group comprising: N-type; and P-type.

7. The method of claim 1 further comprising creating lattice imperfections in the substrate.

8. The method of claim 7 wherein creating the lattice imperfections comprises at least one selected from a group comprising: ion implantation; ion implantation of He+; and exposure of the substrate to radiation by electrons.

9. The method of claim 7 wherein creating the lattice imperfections comprises ion implantation of about 4-5 mega-electron Volt (MeV) He+ helium atoms.

10. The method of claim 7 wherein creating the lattice imperfections comprises exposing the substrate to radiation by electrons at between and including 120 kilogray (kGy) and 250 kGy.

11. The method of claim 1 further comprising:
creating upper lattice imperfections by ion implantation incident initially upon the upper side; and
creating lower lattice imperfections by ion implantation incident initially upon the lower side.

12. The method of claim 1 wherein the upper P-type region has a depth about 10 microns, and the lower P-type region has a depth of about 5 microns.

13. The method of claim 1 wherein, prior to reducing the thickness, the substrate has a thickness of between and including 200 and 800 microns.

14. The method of claim 1 wherein reducing the thickness comprises reducing the thickness to between and comprising 45 to 120 microns.

15. The method of claim 14 wherein reducing the thickness comprises reducing the thickness to about 45 microns for the bipolar junction device rated for 400V service.

16. The method of claim 14 wherein reducing the thickness comprises reducing the thickness to about 70 microns for the bipolar junction device rated for 600V service.

17. The method of claim 1 wherein localized-heat annealing further comprises laser annealing.

18. The method of claim 1 wherein localized-heat annealing further comprises plasma annealing.

19. The method of claim 1 wherein localized-heat annealing further comprises annealing by way of an infrared lamp.

20. A bipolar junction device made using the method of claim 1.
